(19) United States
(12) Patent Application Publication
(10) Pub. No.: US 2013/0192302 A1
(43) Pub. Date: Aug. 1, 2013

(54) CRUCIBLES FOR HOLDING MOLTEN MATERIAL AND METHODS FOR PRODUCING THEM AND FOR THEIR USE

(71) Applicant: MEMC Singapore Pte. Ltd. (UEN200614794D), Singapore (SG)

(72) Inventors: Richard J. Philllips, St. Peters, MO (US); Shawn W. Hayes, Foristell, MO (US); Aditya Deshpande, Chesterfield, MO (US); Jaishankar Kasthuri, Chesterfield, MO (US)

(73) Assignee: MEMC Singapore Pte. Ltd. (UEN200614794D), Singapore (SG)

(21) Appl. No.: 13/739,849

(22) Filed: Jan. 11, 2013

Related U.S. Application Data
(60) Provisional application No. 61/593,565, filed on Feb. 1, 2012.

(51) Int. Cl. C30B 28/06

(52) U.S. Cl. CPC C30B 28/06
USPC 65/26; 65/169; 427/454; 427/452; 65/24

(57) ABSTRACT

Coated crucibles for holding molten material are disclosed. In some embodiments, the crucibles are used to prepare multicrystalline silicon ingots by a directional solidification process. Methods for preparing such crucibles and methods for preparing silicon ingots by use of such crucibles are also disclosed.

### CROSS-REFERENCE TO RELATED APPLICATION

This application claims the benefit of U.S. Provisional Application No. 61/593,565, filed Feb. 1, 2012, which is incorporated herein by reference in its entirety.

### FIELD OF THE DISCLOSURE

The field of the disclosure relates to coated crucibles for holding molten material and, particularly, for use in preparing multicrystalline silicon ingots by a directional solidification process. Other aspects include methods for preparing such crucibles and methods for preparing silicon ingots by use of such crucibles.

### BACKGROUND

Conventional photovoltaic cells, used for the production of solar energy, utilize multicrystalline silicon. Multicrystalline silicon is conventionally produced in a directional solidification (DS) process in which silicon is melted in a crucible and directionally solidified in a separate or in the same crucible. The solidification of the ingot is controlled such that molten silicon solidifies unidirectionally at the solidifying front of the casting. The multicrystalline silicon produced in such a manner is an agglomeration of crystal grains with the orientation of the grains being generally random relative to each other due to the high density of heterogeneous nucleation sites at the crucible wall. The silicon may also be at least partially columnar in nature. Once the multicrystalline ingot is formed, the ingot may be cut into blocks and further cut into wafers. Multicrystalline silicon is generally the preferred silicon source for photovoltaic cells rather than single crystal silicon due to its lower cost resulting from higher throughput rates, less labor-intensive operations and the reduced cost of supplies as compared to typical single crystal silicon production.

During solidification in conventional crucibles, portions of the crucible may enter the melt and form inclusions in the silicon ingot (particularly at the upper portions of the ingot) as the ingot solidifies. Without being bound to a particular theory, it is believed that portions of the mold release coating, in particular release coatings comprising Si₃N₄, may enter the melt. The nitrogen concentration in the melt may reach the solubility limit of nitrogen in silicon such that Si₃N₄ can survive after the solubility limit is reached, leading to the formation of inclusions in the ingot. During and after solidification, the solidified ingot must be released from the crucible without causing cracking of the ingot.

A continuing need exists for crucibles that reduce the amount of inclusions in silicon ingots and that allow the ingot to be released with less incidence of cracking. A continuing need also exists for methods for producing such crucibles and for methods for preparing ingots by use of such crucibles.

This section is intended to introduce the reader to various aspects of art that may be related to various aspects of the disclosure, which are described and/or claimed below. This discussion is believed to be helpful in providing the reader with background information to facilitate a better understanding of the various aspects of the present disclosure. Accordingly, it should be understood that these statements are to be read in this light, and not as admissions of prior art.

### SUMMARY

One aspect of the present disclosure is directed to a crucible for holding molten material. The crucible includes a body having a bottom and a sidewall extending up from the bottom. The bottom and sidewall define a cavity for holding the molten material. The sidewall has an inner surface and an outer surface. The crucible includes a release coating comprising zirconia and a bond coating disposed between the release coating and at least a portion of the inner surface of the sidewall.

Another aspect of the present disclosure is directed to a method for producing a crucible having a body, a bond coating and a release coating. The body has a bottom and a sidewall extending up from the bottom. The bottom and sidewall define a cavity for holding molten material. The sidewall has an inner surface. A molten or partially molten bond material is thermally sprayed on at least a portion of the inner surface of the sidewall. The bond material is solidified to form a bond coating. The bond coating has an inner surface. A molten or partially molten release material is thermally sprayed on at least a portion of the inner surface of the bond coating. The bond material is solidified to form a release coating.

A further aspect of the present disclosure is directed to a method for preparing a multicrystalline silicon ingot. Polycrystalline silicon is loaded into a coated crucible to form a silicon charge. The crucible has a body having a bottom and a sidewall extending up from the bottom. The bottom and sidewall define a cavity for holding the charge. The sidewall has an inner surface and an outer surface. The crucible has a release coating comprising zirconia and a bond coating disposed between the release coating and at least a portion of the inner surface of the sidewall. The silicon charge is heated to a temperature above about the melting temperature of the charge to form a silicon melt. The silicon melt is directionally solidified to form a multicrystalline silicon ingot.

Yet another aspect of the present disclosure is directed to a method for preparing a multicrystalline silicon ingot in a crucible. The crucible comprises a body having a bottom and a sidewall extending up from the bottom. The bottom and sidewall define a cavity for holding a silicon charge. The sidewall has an inner surface and an outer surface. A molten or partially molten bond material is thermally sprayed on at least a portion of the inner surface of the sidewall to form a bond coating. The bond coating has an inner surface. A molten or partially molten release material is thermally sprayed on at least a portion of the inner surface of the bond coating to form a release coating. Polycrystalline silicon is loaded into the coated crucible to form a silicon charge. The silicon charge is heated to a temperature above about the melting temperature of the charge to form a silicon melt. The silicon melt is directionally solidified to form a multicrystalline silicon ingot.

Various refinements exist of the features noted in relation to the above-mentioned aspects of the present disclosure. Further features may also be incorporated in the above-mentioned aspects of the present disclosure as well. These refinements and additional features may exist individually or in any combination. For instance, various features discussed below in relation to any of the illustrated embodiments of the present disclosure may be incorporated into any of the above-described aspects of the present disclosure, alone or in any combination.

### BRIEF DESCRIPTION OF THE DRAWINGS

FIG. 1 is a perspective view of a crucible body.

### DETAILED DESCRIPTION

In accordance with embodiments of the present disclosure, it has been found that crucibles having a bond coating (e.g., oxides or silicates of yttrium, magnesium, calcium, cerium or lanthanum) and a zirconia top coating disposed on the bond coating allow ingots with relatively less inclusions to be prepared. In some embodiments, the crucibles also enhance an ingot-release characteristic of the crucible. Ingot-release characteristics include the ability of the ingot to release the ingot during cooling (i.e., ability of the crucible not to adhere to the ingot) and to release the ingot without causing ingot cracking. Evidence of ingot adhesion includes, for example, (1) a failure of the ingot to release from the crucible even at room temperatures, (2) the amount of ingot cracking upon release and/or (3) the presence and amount of solidified material stuck to the crucible after release of the ingot.

### Crucible Body Starting Material

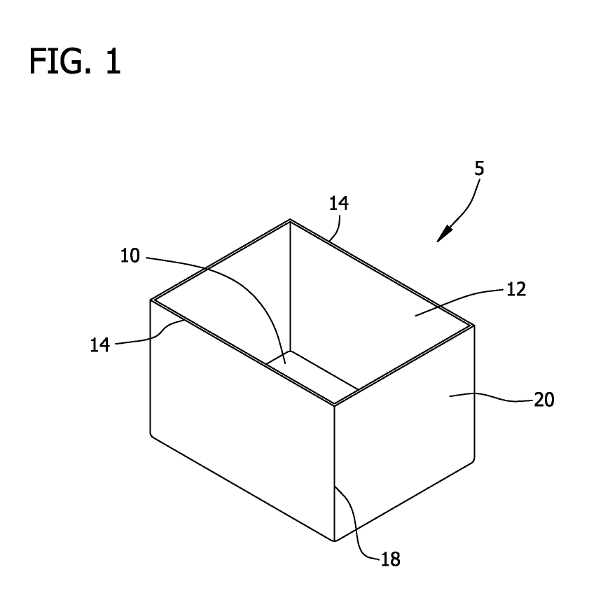

Referring now to FIG. 1, a crucible body for use in embodiments of the present disclosure is generally designated as numeral 5. The crucible body 5 has a bottom 10 and a sidewall 14 that extends from the base or bottom 10. While the crucible body 5 is illustrated with four sidewalls 14 being shown, it should be understood that the crucible body 5 may include fewer than four sidewalls or may include more than four sidewalls without departing from the scope of the present disclosure. Also, the corners 18 between sidewalls 14 may be connected to each other at any angle suitable for forming the enclosure of the crucible body and may be sharp as illustrated in FIG. 1 or may be rounded. In some embodiments, the crucible body has one sidewall that is generally cylindrical in shape. The sidewalls 14 of the crucible body 5 have an inner surface 12 and an outer surface 20. The crucible body 5 is generally open, i.e., the body may not include a top. It should be noted, however, the crucible body 5 may have a top (not shown) opposite the bottom 10 without departing from the scope of the present disclosure.

In several embodiments of the present disclosure, the crucible body 5 has four sidewalls 14 of substantially equal length (e.g., the crucible has a generally square base 10). The length of the sidewalls 14 may be at least about 25 cm, at least about 50 cm, at least about 75 cm, at least about 100 cm or even at least about 125 cm (e.g., from about 25 cm to about 200 cm or from about 50 cm to about 175 cm). The height of the sidewalls 14 may be at least about 15 cm, at least about 25 cm, at least about 35 cm or even at least about 50 cm (e.g., from about 15 cm to about 100 cm or from about 25 cm to about 80 cm). In this regard, the volume of the crucible (in embodiments wherein a square or rectangular base is used or wherein the crucible is cylindrical or round or in embodiments wherein another shape is used) may be at least about 0.005 m³, at least about 0.05 m³, at least about 0.15 m³, at least about 0.25 m³, at least about 0.50 m³ or even at least about 1.00 m³ (e.g., from about 0.005 m³ to about 1.5 m³ or from about 0.25 m³ to about 1.5 m³). Further in this regard, it should be understood that crucible shapes and dimensions other than as described above may be used without departing from the scope of the present disclosure.

The crucible body 5 may be constructed of any material suitable for the solidification of molten material (e.g., solidification of molten silicon). For example, the crucible may be constructed from a material selected from silica, silicon nitride, silicon carbide, graphite, mullite, mixtures and composites thereof. In some embodiments, the crucible body is made of quartz. The material preferably is capable of withstanding temperatures at which material (e.g., silicon) is melted and solidified. For example, the crucible material is suitable for melting and solidifying material at temperatures of at least about 300° C., at least about 1000° C. or even at least about 1580° C. for durations of at least about 10 hours or even as much as 200 hours or more.

The thickness of the bottom 10 and sidewalls 14 may vary depending upon a number of variables including, for example, the strength of material at processing temperatures, the method of crucible construction, the solidified material of choice and the furnace and process design. Generally, the thickness of the crucible body (i.e., sidewalls and/or bottom) may be from about 5 mm to about 50 mm, from about 10 mm to about 40 mm or from about 15 mm to about 25 mm.

### Crucible Coating Materials and Methods for Coating

In some embodiments of the present disclosure, at least a portion of the inner surface 12 of the sidewalls 14 of the crucible body 5 described above is coated with a bond coating and a release coating deposited on the bond coating. The release coating (and possibly also at least a portion of the bond coating) delaminates from the body during release of the solidified ingot which allows the ingot to be released with a lower incidence of ingot cracking. The bond coating also may enhance release of the ingot by acting as a barrier to prevent the release coating from bonding directly with the crucible body.

The bond coating that is deposited between the release coating and at least a portion of the inner surface of the sidewall may be an oxide or silicate chosen from yttria, magnesia, calcia, ceria, lanthanum oxide, yttrium silicate, magnesium silicate, calcium silicate, cerium silicate and lanthanum silicate. The bond coating may contain at least about 2 wt % of one or more of these materials or, as in other embodiments, at least about 10 wt %, at least about 40 wt %, at least about 70 wt %, at least about 80%, at least about 90 wt %, at least about 95 wt % or even at least about 99 wt % of these materials (e.g., from about 10 wt % to about 100 wt %, from about 40 wt % to about 100 wt %, from about 80 wt % to about 100 wt %, from about 90 wt % to about 100 wt % or from about 90 wt % to about 99% of materials selected from yttria, magnesia, calcia, ceria, lanthanum oxide, yttrium silicate, magnesium silicate, calcium silicate, cerium silicate and lanthanum silicate). In some embodiments, the bond coating is yttria (e.g., contains at least about 75 wt % yttria, at least about 90 wt % yttria, at least about 99 wt % yttria or even consists essentially (i.e., consists of yttria and impurities) or consists of yttria.

A release coating is disposed on the surface of the bond coating. The release coating contacts the molten material (e.g., silicon) during ingot growth. The release coating has a composition different than the bond coating and typically comprises zirconia. Preferably the zirconia release coating contains a stabilizer such as yttria, calcia or magnesia. The stabilizer alters the crystal structure of zirconia into a structure that better withstands the high temperatures used during solidification operations. In some embodiments, zirconia in the release coating is fully stabilized. In embodiments wherein yttria is used as the stabilizer, zirconia may be fully stabilized when the molar ratio of yttria to zirconia is at least about 2 to 23 (i.e., about 8% yttria when only zirconia and yttria are present). Accordingly, in embodiments wherein zirconia is fully stabilized, the molar ratio of yttria to zirconia in the release coating may be at least about 2 to 23, at least about 1 to 10, at least about 1 to 5 or at least about 1 to 1 (e.g., from about 2 to 23 to about 2 to 1, from about 2 to 23 to about 1 to 1, from about 2 to 23 to about 1 to 5 or from about 1 to 10 to about 1 to 1).

In other embodiments, zirconia is only partially stabilized (i.e., the molar ratio of yttria to zirconia is less than about 2 to 23 when yttria is used as the stabilizer) or is not stabilized (i.e., contains substantially no stabilizer material). In various embodiments (i.e., stabilized, partially-stabilized, or non-stabilized zirconia), the release coating may contain at least about 30 wt % zirconia or at least about 45 wt %, at least about 60 wt %, at least about 70 wt % or from about 30 wt % to about 100 wt %, from about 30 wt % to about 90 wt %, from about 30 wt % to about 80 wt % or from about 60 wt % to about 80 wt % zirconia.

The bond coating and release coating may be applied by any method available to those of skill in the art. The bond coating and/or release coating may be applied by use of a slip (e.g., application of a liquid coating composition containing the ceramic material and a diluent and other optional additives) followed by one or more sintering operations or by chemical vapor deposition, aerosol spraying or any combination of these operations.

Preferably, the bond coating and/or release coating is applied by thermal spraying. Thermal spraying may involve heating a powder of the coating material (e.g., bond materials such as yttria, magnesia or calcia or release materials such as zirconia (stabilized or otherwise)) to a temperature at which the material is partially or fully molten and spaying the molten material on the crucible. The powder material may be heated by use of a plasma or by use of combustion gases. After application, the molten material cools and solidifies. In this regard, it is preferred that the bond and/or release coating be applied by thermal spraying as thermal spraying has been found to produce a relatively dense and well-adhered coating and ingots produced from such crucibles may have less inclusions than ingots solidified in crucibles in which the coatings were applied by other methods (e.g., slip coatings). The process conditions used during the thermal spraying operation (e.g., particle sizes, temperatures, pressures, ambients, etc.) may be selected from among those known by those of skill in the art and may be selected to produce coatings that fall within the thickness and density ranges described herein.

In some embodiments of the present disclosure, the bond coating has a thickness of at least about 10 μm, at least about 50 μm, at least about 75 μm or at least about 100 μm (e.g., from about 10 μm to about 1 mm, from about 10 μm to about 500 μm or from about 50 μm to about 500 μm). Alternatively or in addition, the thickness of the release coating may be at least about 10 μm, at least about 50 μm, at least about 75 μm or at least about 100 μm (e.g., from about 10 μm to about 1 mm, from about 10 μm to about 500 μm or from about 50 μm to about 500 μm). The density of the bond coating and/or release coating may be at least about 50% (with the remainder being voids in the coating) or, as in other embodiments, at least about 60%, at least about 70%, at least about 80%, at least about 90%, at least about 92%, at least about 94%, at least about 97% or even at least about 99% (e.g., from about 50% to about 100%, from about 70% to about 99% or from about 90% to about 99%).

Generally, the coating compositions herein described may be applied alone or in combination to at least a portion of the inner surface of the sidewall of the crucible or the entire inner surface of the sidewall of the crucible and also to the bottom of the crucible. If the crucible includes more than one sidewall, the coating composition may be applied to at least a portion of the inner surface of one or more sidewalls or the entire surface of one or more sidewalls and may be applied to the entire inner surfaces of all the sidewalls.

### Methods for Preparing an Ingot

In one aspect of the present disclosure, ingots and, in some embodiments, silicon ingots are prepared by use of a coated crucible as described above. The crucible is loaded with a charge of material which is desired to be melted. Typically the material is a metal or metalloid such as, for example, silicon, germanium, gallium nitride or gallium arsenide. In embodiments where multicrystalline silicon ingots produced by a directional solidification process are desired, polycrystalline silicon may be loaded into a coated crucible to form a silicon charge. Coated crucibles to which polycrystalline silicon may be applied are generally described above. Methods for crystallizing are generally described by K. Fujiwara et al. in Directional Growth Medium to Obtain High Quality Polycrystalline Silicon from its Melt, Journal of Crystal Growth 292, p. 282-285 (2006), which is incorporated herein by reference for all relevant and consistent purposes.

Once loaded into the coated crucible of the present disclosure, the charge (e.g., polycrystalline silicon) may be heated to a temperature above about the melting temperature of the charge to form a melt. In embodiments wherein a silicon ingot is desired, the silicon charge may be heated to at least about 1410° C. to form the silicon melt and, in another embodiment, at least about 1450° C. to form the silicon melt. Once the silicon melt has been prepared, the melt may be solidified such as, for example, in a directional solidification process. The ingot may then be cut into one or more pieces with dimensions matching several of the dimensions of a desired solar cell. Wafers may be prepared by slicing these pieces by, for example, use of a wiresaw to produce sliced wafers.

The multicrystalline silicon produced by directional solidification is an agglomeration of crystal grains with the orientation of the grains relative to each other being generally random due to the high density of heterogeneous nucleation sites at the crucible wall. The silicon may also be at least partially columnar in nature. The resulting multicrystalline silicon ingot may have an average nominal crystal grain size of from about 1 mm to about 15 mm and, in other embodiments, has an average nominal crystal grain size of from about 5 mm to about 25 mm or from about 5 mm to about 15 mm.

Silicon wafers may be produced by slicing the ingot using, for example, a wiresaw. The resulting silicon wafers have average nominal crystal grain sizes as described above for multicrystalline ingots.

After release of the ingot, the crucible may be re-used a number of cycles (e.g., at least about two, at least about three, or at least about five or more cycles). In some embodiments, the release coating is re-applied to the crucible before solidification of a subsequent ingot.

When introducing elements of the present disclosure or the embodiment(s) thereof, the articles “a”, “an”, “the” and “said” are intended to mean that there are one or more of the elements. The terms “comprising,” “including,” “containing” and “having” are intended to be inclusive and mean that there may be additional elements other than the listed elements. The use of terms indicating a particular orientation (e.g., “top”, “bottom”, “side”, etc.) is for convenience of description and does not require any particular orientation of the item described.

As various changes could be made in the above constructions and methods without departing from the scope of the disclosure, it is intended that all matter contained in the above description and shown in the accompanying drawing[s] shall be interpreted as illustrative and not in a limiting sense.

1. A crucible for holding molten material, the crucible comprising:
a body having a bottom and a sidewall extending up from the bottom, the bottom and sidewall defining a cavity for holding the molten material, the sidewall having an inner surface and an outer surface;
a release coating comprising zirconia; and
a bond coating disposed between the release coating and at least a portion of the inner surface of the sidewall.

2. The crucible as set forth in claim 1 wherein the release coating comprises at least about 10 wt % zirconia.

3. The crucible as set forth in claim 1 wherein the release coating comprises a stabilizer selected from the group consisting of yttria, calcia and magnesia.

4. The crucible as set forth in claim 3 wherein the zirconia is fully stabilized.

5. The crucible as set forth in claim 3 wherein the stabilizer is yttria.

6. The crucible as set forth in claim 5 wherein the molar ratio of yttria to zirconia is at least about 2 to 23.

7. The crucible as set forth in claim 1 wherein the bond coating comprises an oxide or silicate selected from the group consisting of yttria, magnesia, calcia, ceria, lanthanum oxide, yttrium silicate, magnesium silicate, calcium silicate, cerium silicate and lanthanum silicate.

8. The crucible as set forth in claim 7 wherein the bond coating comprises at least about 10 wt % yttria, magnesia, calcia, ceria, lanthanum oxide, yttrium silicate, magnesium silicate, calcium silicate, cerium silicate and/or lanthanum silicate.

9. The crucible as set forth in claim 1 wherein the bond coating comprises yttria.

10. The crucible as set forth in claim 9 wherein the bond coating comprises at least about 75 wt % yttria.

11. The crucible as set forth in claim 9 wherein the bond coating consists essentially of yttria.

12. The crucible as set forth in claim 1 wherein the body comprises a material selected from silica, silicon nitride, silicon carbide, graphite and mullite.

13. The crucible as set forth in claim 1 wherein the thickness of the bond coating is at least about 10 μm.

14. The crucible as set forth in claim 1 wherein the thickness of the release coating is at least about 10 μm.

15. The crucible as set forth in claim 1 wherein the density of the bond coating is at least about 50%.

16. The crucible as set forth in claim 1 wherein the density of the release coating is at least about 50%.

17. A method for producing a crucible having a body, a bond coating and a release coating, the body having a bottom and a sidewall extending up from the bottom, the bottom and sidewall defining a cavity for holding molten material, the sidewall having an inner surface, the method comprising:
thermal spraying a molten or partially molten bond material on at least a portion of the inner surface of the sidewall;
solidifying the bond material to form a bond coating, the bond coating having an inner surface;
thermal spraying a molten or partially molten release material on at least a portion of the inner surface of the bond coating; and
solidifying the bond material to form a release coating.

18. The method as set forth in claim 17 wherein the release coating comprises at least about 30 wt % zirconia.

19. The method as set forth in claim 17 wherein the release coating comprises a stabilizer selected from the group consisting of yttria, calcia and magnesia.

20. The method as set forth in claim 19 wherein the zirconia is fully stabilized.

21. The method as set forth in claim 19 wherein the stabilizer is yttria.

22. The method as set forth in claim 21 wherein the molar ratio of yttria to zirconia is at least about 2 to 23.

23. The method as set forth in claim 17 wherein the bond coating comprises an oxide or silicate selected from the group consisting of yttria, magnesia, calcia, ceria, lanthanum oxide, yttrium silicate, magnesium silicate, calcium silicate, cerium silicate and lanthanum silicate.

24. The method as set forth in claim 23 wherein the bond coating comprises at least about 40 wt % yttria, magnesia, calcia, ceria, lanthanum oxide, yttrium silicate, magnesium silicate, calcium silicate, cerium silicate and/or lanthanum silicate.

25. The method as set forth in claim 17 wherein the bond coating comprises yttria.

26. The method as set forth in claim 25 wherein the bond coating comprises at least about 90 wt % yttria.

27. The method as set forth in claim 17 wherein the body comprises a material selected from silica, silicon nitride, silicon carbide, graphite and mullite.

28. A method for preparing a multicrystalline silicon ingot, the method comprising:
loading polycrystalline silicon into a the coated crucible set forth in independent claim 1 to form a silicon charge;
heating the silicon charge to a temperature above about the melting temperature of the charge to form a silicon melt; and
directionally solidifying the silicon melt to form a multicrystalline silicon ingot.

29. A method for preparing a multicrystalline silicon ingot in a crucible, the crucible comprising a body having a bottom and a sidewall extending up from the bottom, the bottom and sidewall defining a cavity for holding a silicon charge, the sidewall having an inner surface and an outer surface, the method comprising:
thermal spraying a molten or partially molten bond material on at least a portion of the inner surface of the sidewall to form a bond coating, the bond coating having an inner surface;
thermal spraying a molten or partially molten release material on at least a portion of the inner surface of the bond coating to form a release coating;
loading polycrystalline silicon into the coated crucible to form a silicon charge;
heating the silicon charge to a temperature above about the melting temperature of the charge to form a silicon melt; and
directionally solidifying the silicon melt to form a multicrystalline silicon ingot.

30. The method as set forth in claim 29 wherein the release coating comprises at least about 60 wt % zirconia.

31. The method as set forth in claim 29 wherein the release coating comprises a stabilizer selected from the group consisting of yttria, calcia and magnesia.

32. The method as set forth in claim 31 wherein the zirconia is fully stabilized.

33. The method as set forth in claim 31 wherein the stabilizer is yttria.

34. The method as set forth in claim 33 wherein the molar ratio of yttria to zirconia is at least about 2 to 23.

35. The method as set forth in claim 29 wherein the bond coating comprises an oxide or silicate selected from the group consisting of yttria, magnesia, calcia, ceria, lanthanum oxide, yttrium silicate, magnesium silicate, calcium silicate, cerium silicate and lanthanum silicate.

36. The method as set forth in claim 29 further comprising:
releasing the multicrystalline ingot from the crucible;
thermal spraying a molten or partially molten release material on at least a portion of the inner surface of the bond coating to form a second release coating;
loading polycrystalline silicon into the coated crucible to form a second silicon charge;
heating the second silicon charge to a temperature above about the melting temperature of the charge to form a second silicon melt; and
directionally solidifying the silicon melt to form a second multicrystalline silicon ingot.

37. The method as set forth in claim 36 wherein a second bond coating is not applied to the crucible after the first ingot is released.
